(19) United States
(12) Patent Application Publication
(10) Pub. No.: US 2020/0105646 A1
(43) Pub. Date: Apr. 2, 2020

(54) SEMICONDUCTOR STRUCTURE HAVING THROUGH SILICON VIA STRUCTURE AND METHOD FOR FORMING THE SAME

(71) Applicant: NANYA TECHNOLOGY CORPORATION, New Taipei City (TW)

(72) Inventor: Ting-Cih KANG, New Taipei City (TW)

(21) Appl. No.: 16/148,400

(22) Filed: Oct. 1, 2018

(51) Int. Cl. H01L 23/48; H01L 21/768; H01L 23/00

(52) U.S. Cl. CPC H01L 23/481; H01L 21/76898; H01L 2924/35121; H01L 2224/0557; H01L 24/05

(57) ABSTRACT

The present disclosure provides a semiconductor structure. The semiconductor structure includes a semiconductor substrate, an active device, and a TSV structure. The semiconductor substrate has a first surface and a second surface opposite to the first surface. The active device is disposed in the semiconductor substrate at the first surface. The TSV structure extends through the semiconductor substrate from the first surface to the second surface. In some embodiments, the TSV structure includes a first portion and a second portion coupled to the first portion. The first portion of the TSV structure has a first width, the second portion of the TSV structure has a second width, and the second width of the second portion is greater than the first width of the first portion.

### TECHNICAL FIELD

The present disclosure relates to a semiconductor structure having a through silicon via (TSV) structure and a method for forming the same, and more particularly, to a semiconductor structure having a TSV structure with multiple widths and a method for forming the same.

### DISCUSSION OF THE BACKGROUND

Packaging technology for dies (also referred to as “chips”) including integrated circuit structures has been continuously developed to meet the demand for miniaturization and die-mounting reliability. As the miniaturization and high functionality of electronic products are required, various techniques have been disclosed in the art. For example, by using a stack of at least two dies, i.e., the so-called 3D package, it is possible to provide a product having a package capacity which is twice as large as that obtainable through conventional semiconductor integration processes. In addition, a stacked package provides advantages not only of an increase in capacity but also in mounting density and mounting area utilization efficiency.

A TSV structure is utilized in a 3D package for providing electrical connection between stacked dies. The TSV structure is disposed in a die and extends vertically in the die such that dies are electrically connected with each other through the TSV structure. The TSV structure enables greater density and pitch with good performance.

However, structural issues may arise when attempting to couple multiple dies. One problem is that of thermo-mechanical stresses formed between the TSV structure and the bonding pad as a result of the difference between the coefficients of thermal expansion (CTE) of the TSV structure and the bonding pad. With the purpose of miniaturization, the TSV structures are formed close together. Consequently, the stress fields caused by the difference in CTE interact, further magnifying the stress. This stress causes numerous problems such as TSV delamination and cracking. More seriously, electromigration (EM) failure is often found when a large current density occurs in a small contact area. With the purpose of miniaturization, the contact area between the TSV structure and the bonding pad is reduced, and thus the 3D package suffers from acceleration of EM failure.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a semiconductor structure. The semiconductor structure includes a semiconductor substrate, an active device, and a TSV structure. The semiconductor substrate has a first surface and a second surface opposite to the first surface. The active device is disposed in the semiconductor substrate at the first surface. The TSV structure extends through the semiconductor substrate from the first surface to the second surface. In some embodiments, the TSV structure includes a first portion and a second portion coupled to the first portion. The first portion of the TSV structure has a first width, the second portion of the TSV structure has a second width, and the second width of the second portion is greater than the first width of the first portion.

In some embodiments, the first portion is exposed through the second surface of the semiconductor substrate, and the second portion is exposed through the first surface of the semiconductor substrate.

In some embodiments, a spacing distance between the active device and the second portion of the TSV structure is similar to the first width.

In some embodiments, the first portion is exposed through the first surface of the semiconductor substrate, and the second portion is exposed through the second surface of the semiconductor substrate.

In some embodiments, a spacing distance between the active device and the first portion of the TSV structure is similar to the first width.

In some embodiments, the semiconductor structure further includes a third portion coupled to the first portion. In some embodiments, the third portion has a third width greater than the first width.

In some embodiments, the second portion is exposed through the first surface of the semiconductor substrate, and the third portion is exposed through the second surface the semiconductor substrate. In some embodiments, the first portion is between the second portion and the third portion.

In some embodiments, a ratio of the second width to the first width is between approximately 1.1 and approximately 1.5.

In some embodiments, the first portion has a first length, and the second portion has a second length. In some embodiments, the second length is less than the first length.

In some embodiments, the first portion includes first sidewalls, and the second portion includes second sidewalls. In some embodiments, the first sidewalls are separate from the second sidewalls.

In some embodiments, the TSV structure includes a conductive material and a barrier liner layer located between the semiconductor substrate and the conductive material.

In some embodiments, the semiconductor structure further includes a conductive member disposed on and in contact with the second portion of the TSV structure.

Another aspect of the present disclosure provides a method for forming a semiconductor structure. The method includes the following steps. A semiconductor substrate is etched from a first surface to a second surface opposite to the first surface to form a first trench in the semiconductor substrate. A portion of the first trench is widened at the first surface to form a second trench in the semiconductor substrate. The first trench and the second trench are filled with a conductive material. In some embodiments, the first trench has a first width and the second trench has a second width greater than the first width.

In some embodiments, the widening of the first trench further includes the following steps. A patterned photoresist is disposed over the first surface to expose the first trench and a portion of the semiconductor substrate. A portion of semiconductor substrate is removed to widen the first trench to form the second trench.

In some embodiments, a ratio of the second width to the first width is between approximately 1.1 and approximately 1.5.

In some embodiments, the method further includes disposing an active device in the semiconductor substrate at the first surface. In some embodiments, a spacing distance between the second trench and the active device is similar to the first width of the first trench.

In some embodiments, the method further includes disposing an active device in the semiconductor substrate at the second surface. In some embodiments, a spacing distance between the first trench and the active device is similar to the first width of the first trench.

In some embodiments, the method further includes widening the first trench at the second surface of the semiconductor substrate to form a third trench having a third width greater than the first width.

In some embodiments, a depth of the first trench is greater than a depth of the second trench.

In some embodiments, the method further includes forming a barrier liner layer on sidewalls and bottom surfaces of the first trench and the second trench prior to the forming of the conductive material.

In the present disclosure, the TSV structure includes multiple widths. The TSV structure includes the second portion having a width greater than that of the first portion. Further, the second portion is in contact with the conductive member. Because a contact area between the second portion of the TSV structure and the conductive member is increased, the EM failure issue between the TSV structure and the conductive member is mitigated.

In contrast, with a comparative method applied without forming the second portion having greater width, the TSV structure has less contact area between the conductive member and the TSV structure. Accordingly, EM failure is accelerated, and thus reliability of the semiconductor structure is adversely affected.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description.

FIG. 1 is a flow diagram illustrating a method for preparing a semiconductor structure, in accordance with some embodiments of the present disclosure.

FIGS. 2A to 2F are schematic diagrams illustrating various fabrication stages of the method for preparing the semiconductor structure in accordance with a first embodiment of the present disclosure.

FIG. 3 is a top view of the semiconductor structure in accordance with embodiments of the present disclosure.

FIGS. 4A to 4B are schematic diagrams illustrating various fabrication stages of the method for preparing the semiconductor structure in accordance with a second embodiment of the present disclosure.

FIGS. 5A to 5F are schematic diagrams illustrating various fabrication stages of the method for preparing the semiconductor structure in accordance with a third embodiment of the present disclosure.

FIGS. 6A to 6B are schematic diagrams illustrating various fabrication stages of the method for preparing the semiconductor structure in accordance with a fourth embodiment of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

As used herein, the terms “patterning” or “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer. The patterning process includes forming a mask on the existing film or layer and removing the unmasked film or layer with an etch process or other removal process. The mask can be a photoresist or a hard mask. In some embodiments, a patterning process is adopted to form a patterned layer directly on a surface. The patterning process includes forming a photosensitive film on the surface, conducting a photolithography process, and performing a developing process. The remaining photosensitive film is retained and integrated into the semiconductor device.

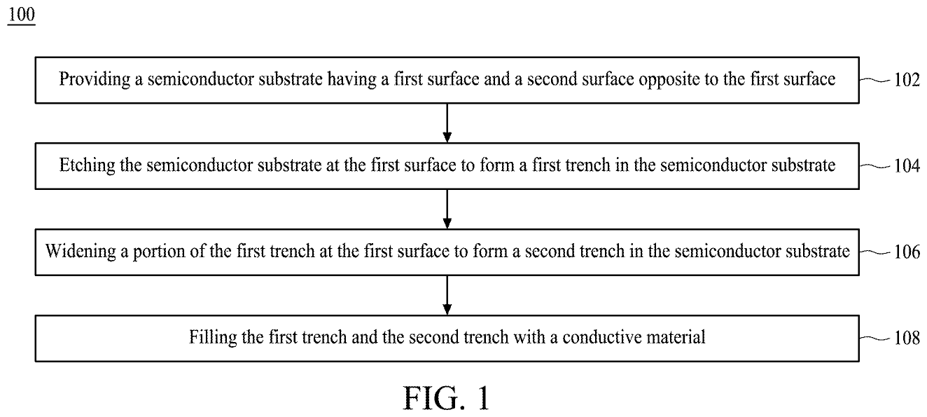

FIG. 1 is a flow diagram illustrating a method for preparing a semiconductor structure in accordance with some embodiments of the present disclosure. The method for preparing the semiconductor structure 100 includes a step 102, providing a semiconductor substrate having a first surface and a second surface opposite to the first surface. The method for preparing the semiconductor structure 100 further includes a step 104, etching the semiconductor substrate at the first surface to form a first trench in the semiconductor substrate. The method for preparing the semiconductor structure 100 further includes a step 106, widening a portion of the first trench at the first surface to form a second trench in the semiconductor substrate. The method for preparing the semiconductor structure 100 further includes a step 108, filling the first trench and the second trench with a conductive material. The method for preparing the semiconductor structure 100 will be further described in embodiments below.

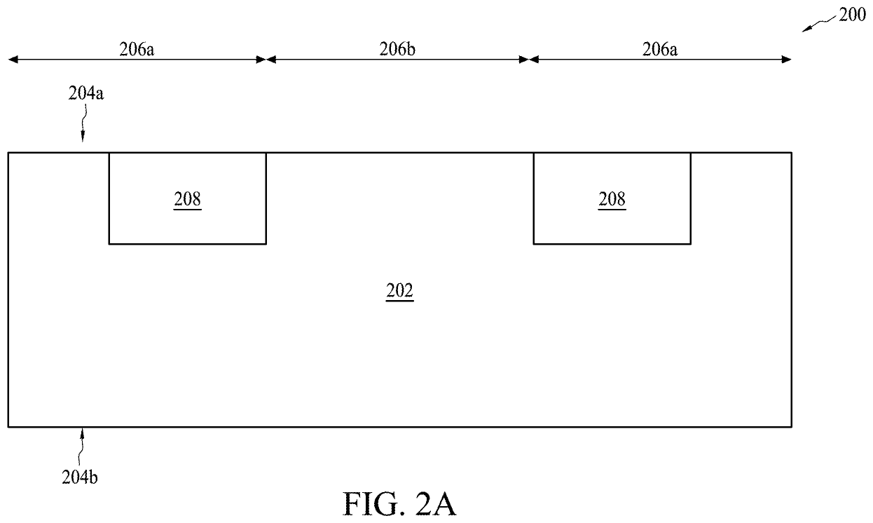

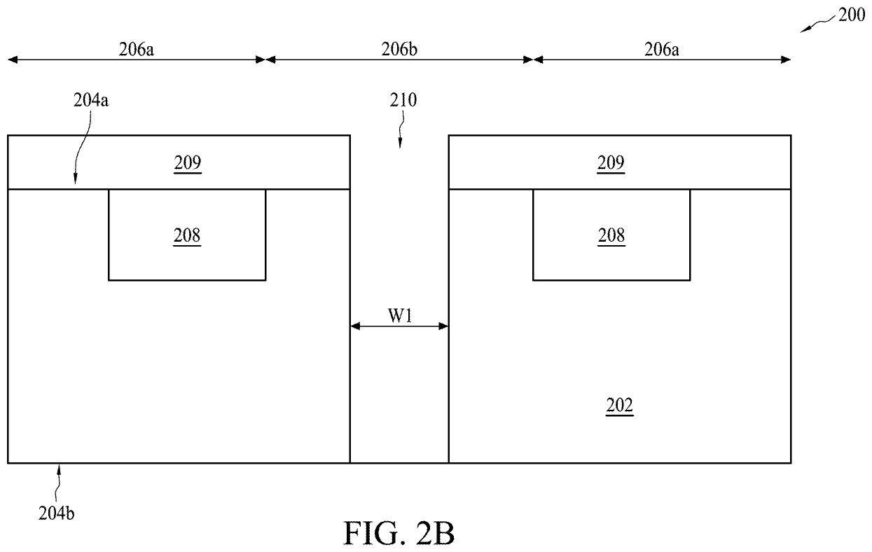

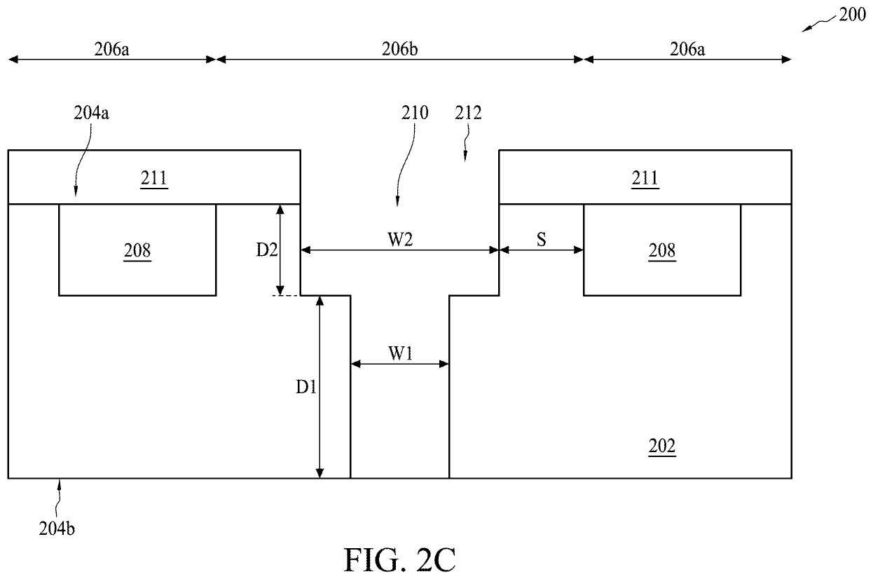

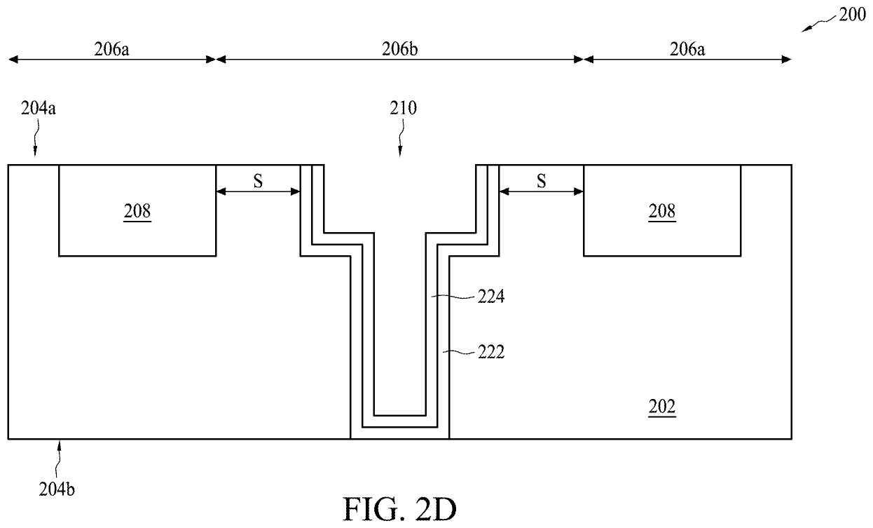

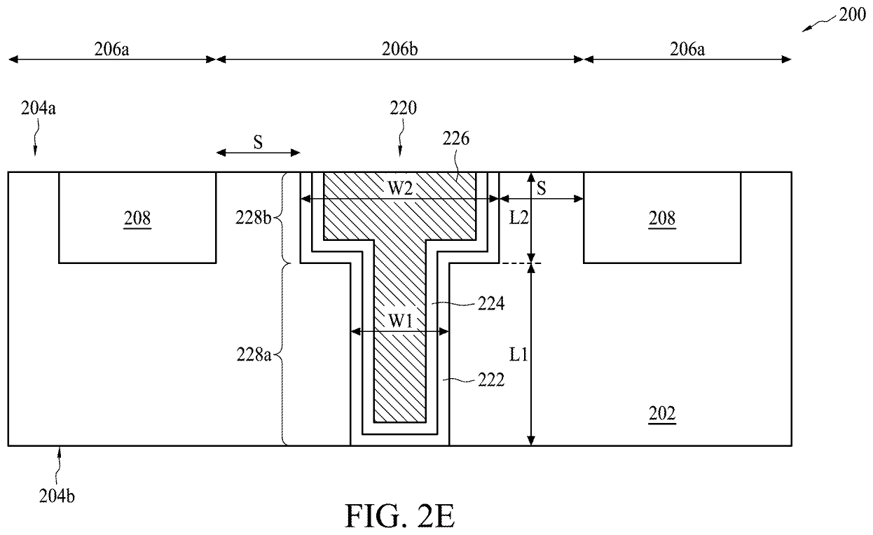

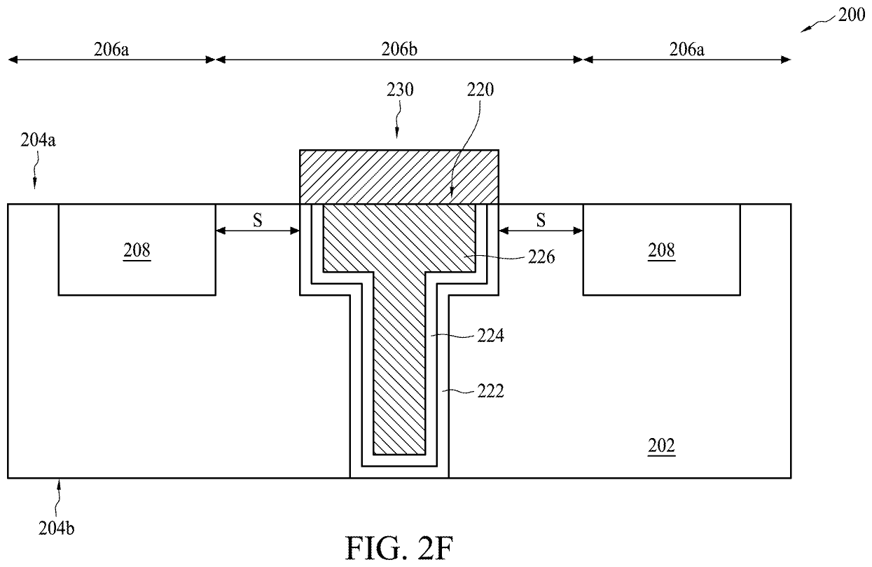

FIGS. 2A to 2F are schematic diagrams illustrating various fabrication stages according to the method for preparing a semiconductor structure in accordance with a first embodiment of the present disclosure. Referring to FIG. 2A, a semiconductor substrate 202 can be provided according to step 102. The substrate 202 can include silicon (Si), gallium (Ga), gallium arsenide (GaAs), gallium nitride (GaN), strained silicon, silicon-germanium (Site), silicon carbide (SiC), diamond, epitaxy layer or a combination thereof, but the disclosure is not limited thereto. The semiconductor substrate 202 has a front surface 204a and a back surface 204b, as shown in FIG. 2A. In some embodiments, the front surface 204a can be referred to as an active surface. In some embodiments, the semiconductor substrate 202 has a plurality of device regions 206a and at least a connection region 206b, defined on the semiconductor substrate 202. In some embodiments, the connection region 206b can be defined between the device regions 206a, but the disclosure is not limited thereto. An active device 208 is disposed in each of the plurality of device regions 206a at the front surface 204a, as shown in FIG. 2A. In some embodiments, the active device 208 can be, for example but not limited thereto, any of various n-type metal-oxide-semiconductor (NMOS) or p-type metal-oxide-semiconductor (PMOS) devices such as transistors, memories, or the like. In some embodiments, the active device 208 can be any of capacitors, resistors, diodes, photo diodes, fuses, or the like.

Referring to FIG. 2B, a patterned photoresist layer 209 is disposed over the front surface 204a of the semiconductor substrate 202. The patterned photoresist layer 209 covers the active devices 208 in the device regions 206a and a portion of the connection region 206b, as shown in FIG. 2B. Further, the patterned photoresist layer 209 exposes a portion of the semiconductor substrate 202 in the connection region 206b. Subsequently, the semiconductor substrate 202 is etched at the front surface 204a to form a first trench 210 in the semiconductor substrate 202, according to step 104. As shown in FIG. 2B, the first trench 210 extends vertically from the front surface 204a to the back surface 204b. A width W1 of the first trench 210 is between approximately 8 μm and approximately 30 μm, but the disclosure is not limited thereto. It should be noted that the first trench 210 is formed in the connection region 206b and is separate from the active devices 208. After the forming of the first trench 210, the patterned photoresist 209 is removed.

Referring to FIG. 2C, another patterned photoresist layer 211 is disposed over the front surface 204a of the semiconductor substrate 202. As shown in FIG. 2C, the patterned photoresist layer 211 exposes the first trench 210 and a portion of the semiconductor substrate 202 in the connection region 206b. Additionally, the active devices 208 in the device regions 206a are covered and protected by the patterned photoresist layer 211. Subsequently, the portion of the semiconductor substrate 202 exposed through the patterned photoresist layer 211 is removed. Accordingly, a portion of the first trench 210 is widened at the front surface 204a to form a second trench 212 according to step 106. As shown in FIG. 2C, the second trench 212 and the first trench 210 are coupled. The second trench 212 has a width W2, and the width W2 of the second trench 212 is greater than the width W1 of the first trench 210. Further, a ratio of the width W2 of the second trench 212 to the width W1 of the first trench 210 is between approximately 1.1 and approximately 1.5, but the disclosure is not limited thereto. The first trench 210 has a depth D1, and the second trench 212 has a depth D2. In some embodiments, the depth D2 of the second trench 212 is less than the depth D1 of the first trench 210. In the first embodiment, both the second trench 212 and the active devices 208 are at the front surface 204a of the semiconductor substrate 202. However, the second trench 212 is separate from the active devices 208, as shown in FIG. 2C. Further, a spacing distance S between the active device 208 and the second trench 212 is similar to the width W1 of the first trench 210, but the disclosure is not limited thereto. The patterned photoresist layer 211 is removed after the forming of the second trench 212.

Referring to FIG. 2D, an insulating liner layer 222 is formed on sidewalls and bottom surfaces of the first trench 210 and the second trench 212. The insulating liner layer 222 can include silicon oxide (SiO), silicon nitride (SiN), or silicon oxynitride (SiON), but the disclosure is not limited thereto. A barrier liner layer 224 is formed on the insulating liner layer 222, and over the sidewalls and bottom surfaces of the first trench 210 and the second trench 212. The barrier liner layer 224 can include tantalum (Ta), tantalum nitride (TaN), titanium (Ti), titanium nitride (TiN), cobalt tungsten (CoW), aluminum, (Al), Al alloys, or combinations thereof, but the disclosure is not limited thereto. In some embodiments, a seed layer (not shown) can be formed on the barrier liner layer 224, but the disclosure is not limited thereto.

Referring to FIG. 2E, after the forming of the barrier liner layer 224 or the seed layer, a conductive material 226 is formed. As shown in FIG. 2E, the first trench 210 and the second trench 212 are filled with the conductive material 226, according to step 108. Accordingly, a TSV structure 220 is obtained.

Referring to FIG. 2F, in some embodiments, a conductive member 230 can be disposed on the TSV structure 220 and in contact with the TSV structure 220. In some embodiments, the conductive member 230 can be a bonding pad, but the disclosure is not limited thereto.

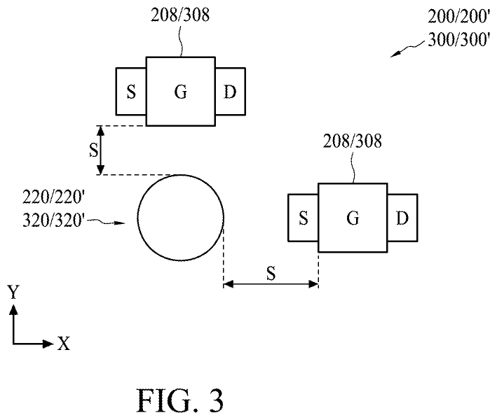

Referring to FIGS. 2E and 3, the FIG. 3 is a top view of the semiconductor structure 200 provided by the first embodiment. It should be noted that the conductive member 230, as shown in FIG. 2F, is omitted in FIG. 3 to emphasize the relationship between the TSV structure 220 and the active device 208, but those skilled in the art can realize the placement of the conductive member 230 according to FIG. 2F. According to the first embodiment, the semiconductor structure 200 includes the semiconductor substrate 202, the active device 208, and the TSV structure 220. As shown in FIG. 2E, the semiconductor substrate 202 of the semiconductor structure 200 has the front surface 204a and the back surface 204b. The active device 208 is disposed in the semiconductor substrate 202 at the front surface 204a. The TSV structure 220 extends through the semiconductor substrate 202 from the front surface 204a to the back surface 204b. In some embodiments, the TSV structure 220 can include the insulating liner layer 222, the barrier liner layer 224 and the conductive material 226. In some embodiments, the TSV structure 220 can further include a seed layer.

According to the first embodiment, the TSV structure 220 includes a first portion 228a and a second portion 228b coupled to each other. The first portion 228a has first sidewalls, the second portion 228b has second sidewalls, and the first sidewalls are separate from the second sidewalls. In other words, the first sidewalls of the first portion 228a and the second sidewalls of the second portion 228b are discontinuous, as shown in FIG. 2E. The first portion 228a has a length L1, and the second portion 228b has a length L2. The length L1 of the first portion 228a is greater than the length L2 of the second portion 228b. In some embodiments, ratio of the length L2 of the second portion 228b to the length L1 of the first portion 228a is between approximately 0.03 and approximately 0.1, but the disclosure is not limited thereto. In some embodiments, the length L1 of the first portion 228a is similar to the depth D1 of the first trench 210, and the length L2 of the second portion 228b is similar to the depth D2 of the second trench 212, but the disclosure is not limited thereto.

The first portion 228a has the width W1, and the second portion 228b has the width W2. The width W2 of the second portion 228b is greater than the width W1 of the first portion 228a, as shown in FIG. 2E. The ratio of the width W2 of the second portion 228b to the width W1 of the first portion 228a is between approximately 1.1 and approximately 1.5, but the disclosure is not limited thereto. In other words, the TSV structure 220 includes a T-shaped configuration with the first portion 228a serving as the body and the second portion 228b serving as the head of the T-shaped configuration. The first portion 228a is exposed through the back surface 204b of the semiconductor substrate 202, while the second portion 228b and the active devices 208 are exposed through the front surface 204a of the semiconductor substrate 202. In some embodiments, the spacing distance S between the active device 208 and the second portion 228a of the TSV structure 220 is similar to the width W1 of the first portion 228a, but the disclosure is not limited thereto. In some embodiments, the spacing distance S between the active device 208 and the second portion 228a of the TSV structure 220 is greater than the width W1 of the first portion 228a, but the disclosure is not limited thereto. In some embodiments, the semiconductor structure 200 can include the conductive member 230 (shown in FIG. 2F), and the conductive member 230 is disposed on and in contact with the second portion 228b of the TSV structure 220.

Referring to FIGS. 2E, 2F and 3, the spacing distance S between the second portion 228b of the TSV structure 220 and the active device 208 is also referred to as a distance between the active device 208 and a keep-out zone (KOZ), which is used to define a region where no devices may be placed. According to the first embodiment, the spacing distance S is similar to the width W1 of the first portion 228a of the TSV structure 220. Therefore, stress induced by the TSV structure 220 on the active device 208 is negligible. More importantly, since the width W2 of the second portion 228b is greater than the width W1 of the first portion 228a, a contact area between the conductive member 230 and the second portion 228b is increased. Accordingly, the EM failure issue between the TSV structure 220 and the conductive member 230 is mitigated because the larger contact area between the TSV structure 220 and the conductive member 230.

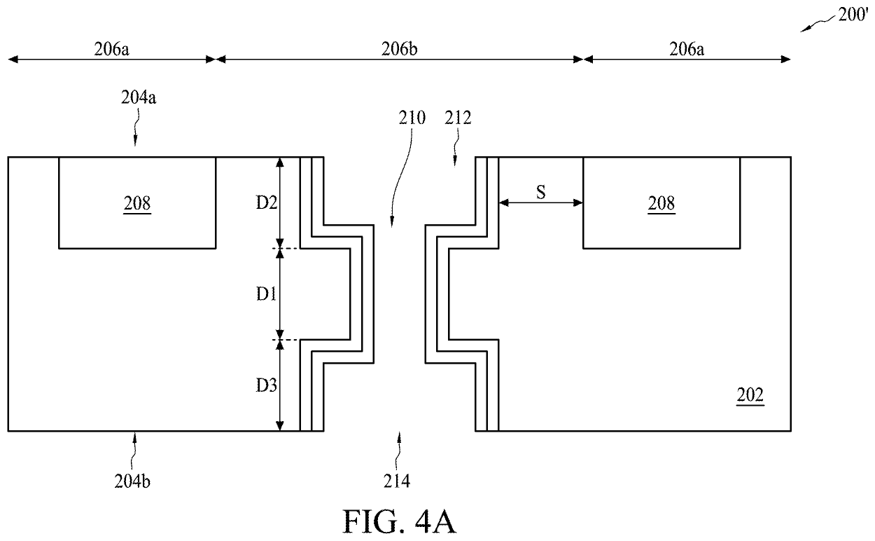

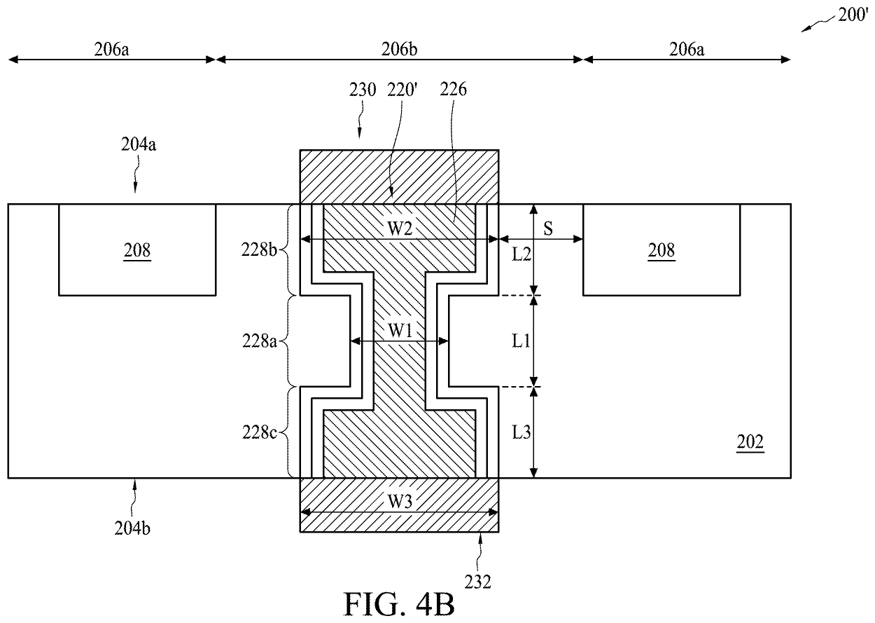

FIGS. 4A to 4B are schematic diagrams illustrating fabrication stages of the method for preparing a semiconductor structure 200′ in accordance with the second embodiment of the present disclosure. It should be understood that similar features in the first and second embodiments can include similar materials and are depicted by the same numerals, and thus descriptions of such details are omitted in the interest of brevity. Referring to FIG. 4A, a semiconductor substrate 202 can be provided according to step 102. The semiconductor substrate 202 has a front surface 204a and a back surface 204b, as shown in FIG. 4A. In some embodiments, the semiconductor substrate 202 has a plurality of device regions 206a and at least a connection region 206b defined on the semiconductor substrate 202. An active device 208 is disposed in each of the plurality of device regions 206a, as shown in FIG. 4A.

According to step 104, the semiconductor substrate 202 is etched at the front surface 204a to form a first trench 210 in the semiconductor substrate 202. According to step 106, a portion of the first trench 210 is widened at the front surface 204a to form a second trench 212. According to the second embodiment, a portion of the first trench 210 is further widened at the back surface 204b of the semiconductor substrate 202 to form a third trench 214, as shown in FIG. 4A. The first trench 210 has a width W1, the second trench 212 has a width W2, and the third trench 214 has a width W3. The width W2 of the second trench 212 and the width W3 of the third trench 214 are greater than the width W1 of the first trench 210. In some embodiments, the width W2 of the second trench 212 and the width W3 of the third trench 214 are different from each other. In alternative embodiments, the width W2 of the second trench 212 and the width W3 of the third trench 214 are similar.

Referring to FIG. 4B, an insulating liner layer 222 is formed on sidewalls of the first trench 210, the second trench 212 and the third trench 214. Further, the insulating liner layer 222 is formed on bottom surfaces of the second trench 212 and the third trench 214. A barrier liner layer 224 is formed on the insulating liner layer 222, and over the sidewalls and bottom surfaces of the first trench 210, the second trench 212 and the third trench 214. In some embodiments, a seed layer (not shown) can be formed on the barrier liner layer 224 but the disclosure is not limited thereto.

Still referring to FIG. 4B, after the forming of the barrier liner layer 224 or the seed layer, a conductive material 226 is formed. As shown in FIG. 4B, the first trench 210, the second trench 212 and the third trench 214 are filled with the conductive material 226, according to step 108. Accordingly, a TSV structure 220′ is obtained.

Referring to FIG. 4B, in some embodiments, a conductive member 230 can be disposed on the TSV structure 220′ at the front surface 204a and in contact with the TSV structure 220′. In some embodiments, the conductive member 230 can be a bonding pad, but the disclosure is not limited thereto. Further, another conductive member 232 can be disposed on the TSV structure 220′ at the back surface 204b and in contact with the TSV structure 220′. In some embodiments, the conductive member 232 can be a bonding pad, but the disclosure is not limited thereto.

Referring to FIGS. 4B and 3, the FIG. 3 is a top view of the semiconductor structure 200′ according to the second embodiment. It should be noted that the conductive member 230 is omitted in FIG. 3 to emphasize the relationship between the TSV structure 220′ and the active device 208, but those skilled in the art can realize the placement of the conductive member 230 according to FIG. 4B. According to the second embodiment, the semiconductor structure 200′ includes the semiconductor substrate 202, the active device 208, and the TSV structure 220′. It should be noted that description of similar features in the first and second embodiments are omitted in the interest of brevity, and only the differences are described.

The TSV structure 220′ provided by the second embodiment includes a first portion 228a, a second portion 228b and a third portion 228c coupled to each other. The first portion 228a is sandwiched between the second portion 228b and the third portion 228c. The first portion 228a has first sidewalls, the second portion 228b has second sidewalls, and the third portion 228c has third sidewalls. The first sidewalls, the second sidewalls and the third sidewalls are separate from each other. In other words, the first sidewalls of the first portion 228a, the second sidewalls of the second portion 228b and the third sidewalls of the third portion 228c are discontinuous, as shown in FIG. 4B. A length L1 of the first portion 228a is greater than a length L2 of the second portion 228b and a length L3 of the third portion 228c. In some embodiments, the length L2 of the second portion 228b and the length L3 of the third portion 228c are different. In alternative embodiments, the length L2 of the second portion 228b and the length L3 of the third portion 228c are similar. In some embodiments, the length L1 of the first portion 228a is similar to the depth D1 of the first trench 210, the length L2 of the second portion 228b is similar to the depth D2 of the second trench 212, and the length L3 of the third portion 228c is similar to the depth D3 of the third trench 214, but the disclosure is not limited thereto.

The first portion 228a has a width W1, the second portion 228b has a width W2, and the third portion 228c has a width W3. The width W2 of the second portion 228b and the width W3 of the third portion 228c are greater than the width W1 of the first portion 228a, as shown in FIG. 4B. A ratio of the width W2 of the second portion 228b to the width W1 of the first portion 228a is between approximately 1.1 and approximately 1.5, but the disclosure is not limited thereto. A ratio of the width W3 of the third portion 228c to the width W1 of the first portion 228a is between approximately 1.1 and approximately 1.5, but the disclosure is not limited thereto. In other words, the TSV structure 220′ includes an H-shaped configuration with the first portion 228a serving as a bridge between the second portion 228b and the third portion 228c. The third portion 228c is exposed through the back surface 204b of the semiconductor substrate 202, while the second portion 228b and the active devices 208 are exposed through the front surface 204a of the semiconductor substrate 202. A spacing distance S between the active device 208 and the second portion 228b of the TSV structure 220′ is similar to the width W1 of the first portion 228a, but the disclosure is not limited thereto. In some embodiments, the spacing distance S between the active device 208 and the second portion 228b of the TSV structure 220′ is greater than the width W1 of the first portion 228a, but the disclosure is not limited thereto. In some embodiments, the semiconductor structure 200′ can include the conductive member 230 disposed on and in contact with the second portion 228b of the TSV structure 220′. In some embodiments, the semiconductor structure 200′ can include the conductive member 232 disposed on and in contact with the third portion 228c of the TSV structure 220′.

As mentioned above, the spacing distance S between the second portion 228b of the TSV structure 220′ and the active device 208 is similar to the width W1 of the first portion 228a of the TSV structure 220′. Therefore, stress induced by the TSV structure 220′ on the active device 208 is negligible. More importantly, since the width W2 of the second portion 228b and the width W3 of the third portion 228c is greater than the width W1 of the first portion 228a, a contact area between the conductive member 230 and the second portion 228b is increased, and a contact area between the conductive member 232 and the third portion 228b is increased. Accordingly, the EM failure issue between the TSV structure 220′ and the conductive members 230 and 232 is mitigated.

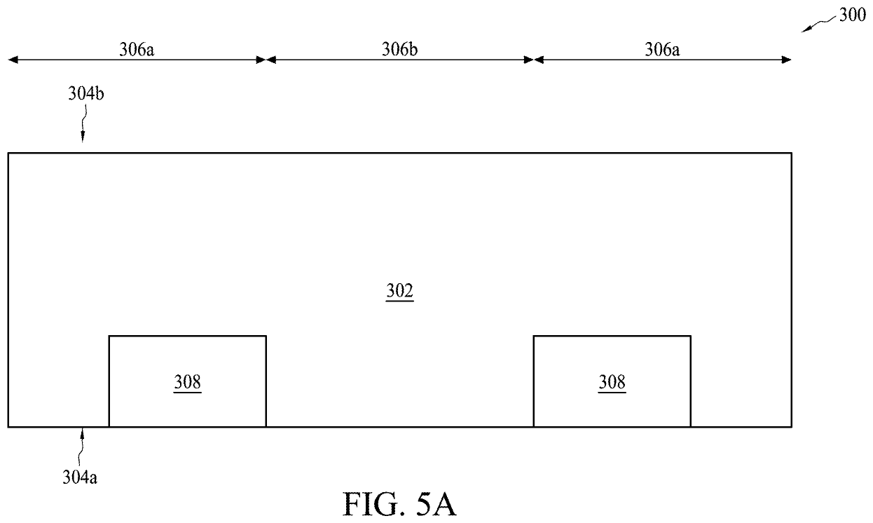

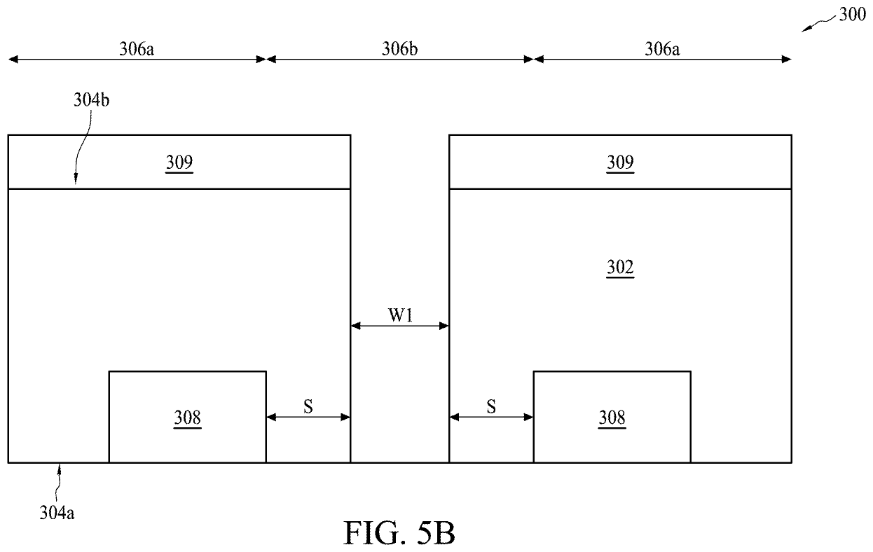

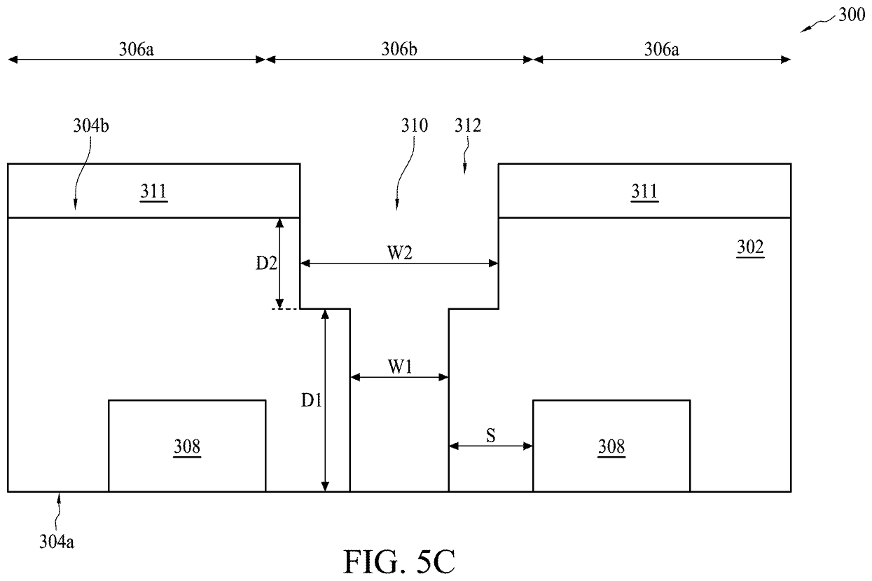

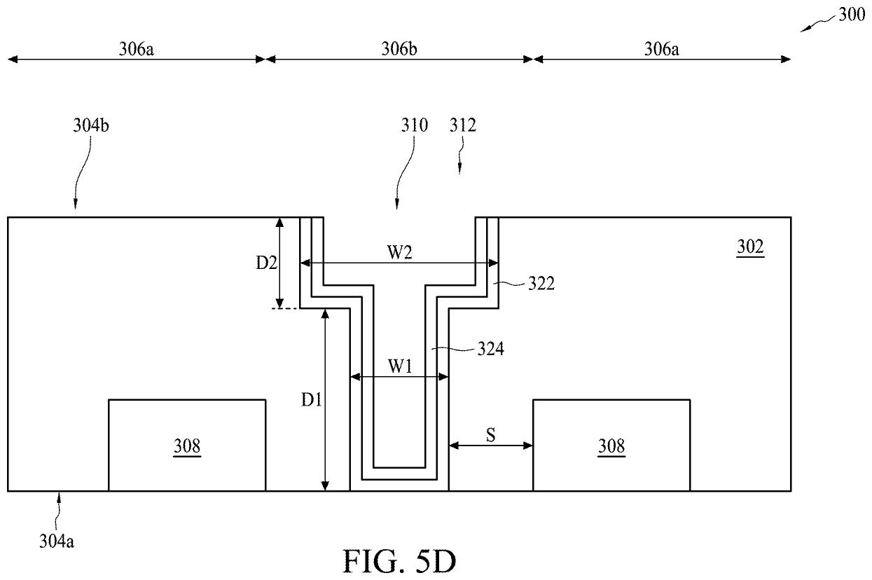

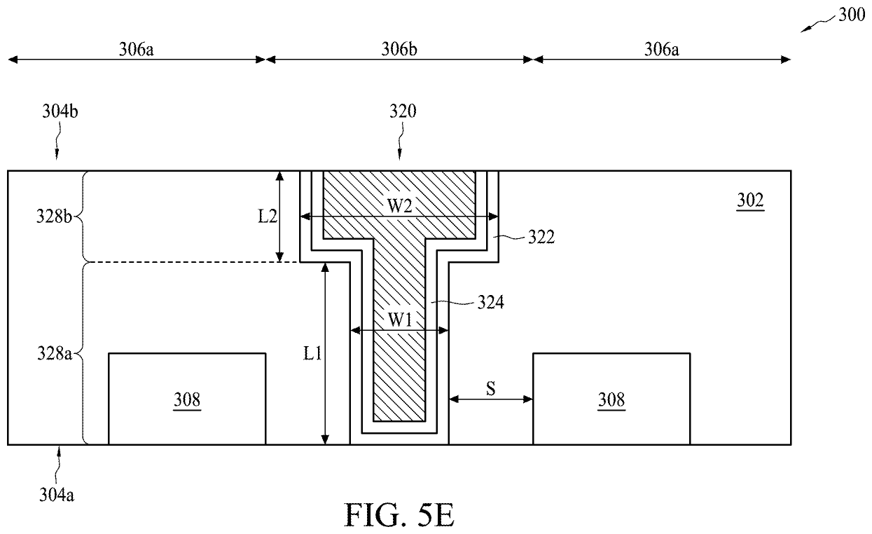

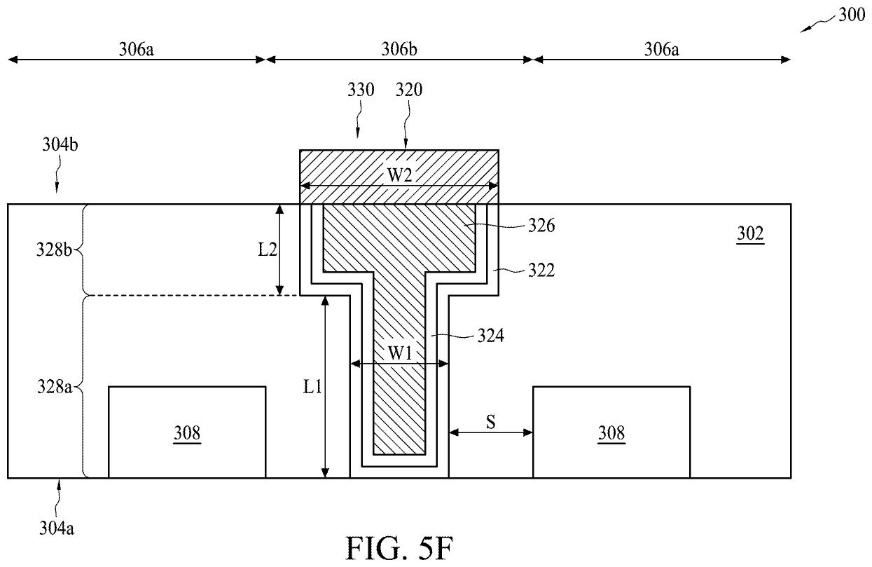

FIGS. 5A to 5F are schematic diagrams illustrating various fabrication stages of the method for preparing a semiconductor structure in accordance with a third embodiment of the present disclosure. It should be understood that similar features in the first and third embodiments can include similar materials, and thus descriptions of such details are omitted in the interest of brevity. Referring to FIG. 5A, a semiconductor substrate 302 can be provided according to step 102. The semiconductor substrate 302 has a front surface 304a and a back surface 304b, as shown in FIG. 5A. In some embodiments, the semiconductor substrate 302 has a plurality of device regions 306a and at least a connection region 306b defined thereon. An active device 308 is disposed in each of the plurality of device regions 306a, as shown in FIG. 5A. In some embodiments, the active device 308 can be, for example but not limited thereto, any of various NMOS and PMOS devices such as transistors, memories, or the like. In some embodiments, the active device 308 can be any of capacitors, resistors, diodes, photo diodes, fuses, or the like.

Referring to FIG. 5B, a patterned photoresist 309 is disposed over the back surface 304b of the semiconductor substrate 302. The patterned photoresist 309 exposes a portion of the back surface 304b of the semiconductor substrate 302 in the connection region 306b. Subsequently, the semiconductor substrate 302 is etched at the back surface 304b to form a first trench 310 in the semiconductor substrate 302, according to step 104. As shown in FIG. 5B, the first trench 310 extends vertically from the back surface 304b to the front surface 304a. A width W1 of the first trench 310 is between approximately 8 μm and approximately 30 μm, but the disclosure is not limited thereto. It should be noted that the first trench 310 is formed in the connection region 306b and is separate from the active devices 308. In the third embodiment, both the first trench 310 and the active devices 308 are at the front surface 304a of the semiconductor substrate 302. However, the first trench 310 is separate from the active devices 308, as shown in FIG. 5B. A spacing distance S between the first trench 310 and the active devices 308 is similar to the width W1 of the first trench 310, but the disclosure is not limited thereto. After the forming of the first trench 310, the patterned photoresist 309 is removed.

Referring to FIG. 5C, another patterned photoresist layer 311 is disposed over the back surface 304b of the semiconductor substrate 302. As shown in FIG. 5C, the patterned photoresist layer 311 exposes the first trench 310 and a portion of the back surface 304b of the semiconductor substrate 302 in the connection region 306b. Subsequently, the portion of the semiconductor substrate 302 exposed through the patterned photoresist layer 311 is removed. Accordingly, a portion of the first trench 310 is widened at the back surface 304b to form a second trench 312 according to step 106. As shown in FIG. 5C, the second trench 312 and the first trench 310 are coupled. The second trench 312 has a width W2, and the width W2 of the second trench 312 is greater than the width W1 of the first trench 310. Further, a ratio of the width W2 of the second trench 312 to the width W1 of the first trench 310 is between approximately 1.1 and approximately 1.5, but the disclosure is not limited thereto. The first trench 310 has a depth D1, and the second trench 312 has a depth D2. In some embodiments, the depth D2 of the second trench 312 is less than the depth D1 of the first trench 310. The patterned photoresist layer 311 is removed after the forming of the second trench 312.

Referring to FIG. 5D, an insulating liner layer 322 is formed on sidewalls and bottom surfaces of the first trench 310 and the second trench 312. A barrier liner layer 324 is formed on the insulating liner layer 322, and over the sidewalls and bottom surfaces of the first trench 310 and the second trench 312. In some embodiments, a seed layer (not shown) can be formed on the barrier liner layer 324, but the disclosure is not limited thereto.

Referring to FIG. 5E, after the forming of the barrier liner layer 324 or the seed layer, a conductive material 326 is formed. As shown in FIG. 5E, the first trench 310 and the second trench 312 are filled with the conductive material 326, according to step 108. Accordingly, a TSV structure 320 is obtained.

Referring to FIG. 5F, in some embodiments, a conductive member 330 can be disposed on the TSV structure 320 and in contact with the TSV structure 320. In some embodiments, the conductive member 330 can be a bonding pad, but the disclosure is not limited thereto.

Referring to FIGS. 5E and 3, the FIG. 3 is a top view of the semiconductor structure 300 provided by the third embodiment. It should be noted that the conductive member 330 is omitted from FATS. 5E and 3 to emphasize the relationship between the TSV structure 320 and the active device 308, but those skilled in the art can realize the placement of the conductive member 330 according to FIG. 5F. According to the third embodiment, the semiconductor structure 300 includes the semiconductor substrate 302, the active device 308, and the TSV structure 320. As shown in FIG. 5E, the semiconductor substrate 302 of the semiconductor structure 300 has the front surface 304a and the back surface 304b. The active device 308 is disposed in the semiconductor substrate 302 at the front surface 304a. The TSV structure 320 extends through the semiconductor substrate 302 from the back surface 304b to the front surface 304a. In some embodiments, the TSV structure 320 can include the insulating liner layer 322, the barrier liner layer 324 and the conductive material 326. In some embodiments, the TSV structure 320 can further include a seed layer.

According to the third embodiment, the TSV structure 320 includes a first portion 328a and a second portion 328b coupled to each other. The first portion 328a has first sidewalls, the second portion 328b has second sidewalls, and the first sidewalls are separate from the second sidewalls. In other words, the first sidewalls of the first portion 328a and the second sidewalls of the second portion 328b are discontinuous, as shown in FIG. 5E. The first portion 328a has a length L1, and the second portion 328b has a length L2. The length L1 of the first portion 328a is greater than the length L2 of the second portion 328b. In some embodiments, the length L1 of the first portion 328a is similar to the depth D1 of the first trench 310, and the length L2 of the second portion 328b is similar to the depth D2 of the second trench 312, but the disclosure is not limited thereto.

The first portion 328a has the width W1, and the second portion 328b has the width W2. The width W2 of the second portion 328b is greater than the width W1 of the first portion 328a. The ratio of the width W2 of the second portion 328b to the width W1 of the first portion 328a is between approximately 1.1 and approximately 1.5, but the disclosure is not limited thereto. In other words, the TSV structure 320 includes a T-shaped configuration with the first portion 328a serving as the body and the second portion 328b serving as the head of the T-shaped configuration. The second portion 328b is exposed through the back surface 304b of the semiconductor substrate 302, while the first portion 328a and the active devices 308 are exposed through the front surface 304a of the semiconductor substrate 302. The spacing distance S between the active device 308 and the first portion 328a of the TSV structure 320 is similar to the width W1 of the first portion 328a, but the disclosure is not limited thereto. In some embodiments, the semiconductor structure 300 can include the conductive member 330 (shown in FIG. 5F), wherein the conductive member 330 is disposed on and in contact with the second portion 328b of the TSV structure 320.

Referring to FIGS. 5F and 3, the spacing distance S between the first portion 328a of the TSV structure 320 and the active device 308 is also referred to as a distance between the active device 308 and a keep-out zone (KOZ), which is used to define a region where no device may be placed. According to the third embodiment, the spacing distance S is similar to the width W1 of the first portion 328a of the TSV structure 320. Therefore, stress induced by the TSV structure 320 on the active device 308 is negligible. More importantly, since the width W2 of the second portion 328b is greater than the width W1 of the first portion 328a, a contact area between the conductive member 330 and the second portion 328b is increased. Accordingly, the EM failure issue between the TSV structure 320 and the conductive member 330 is mitigated.

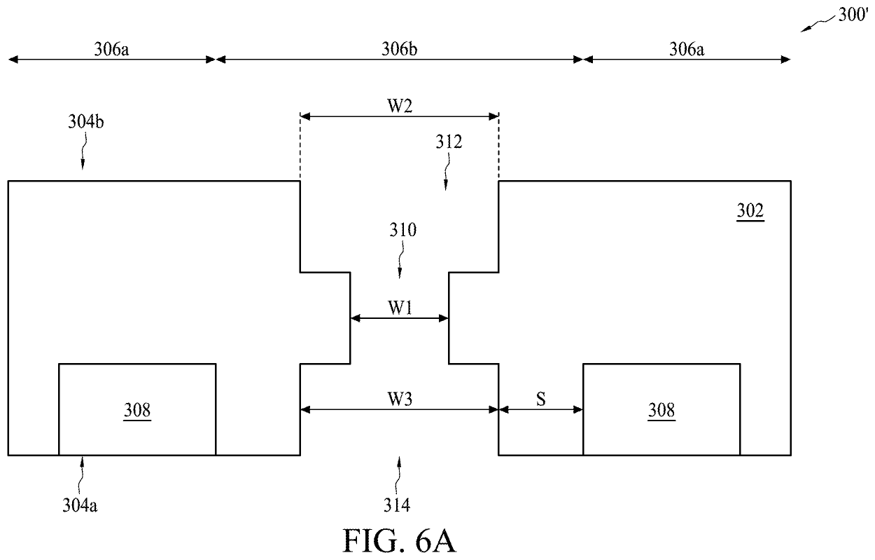

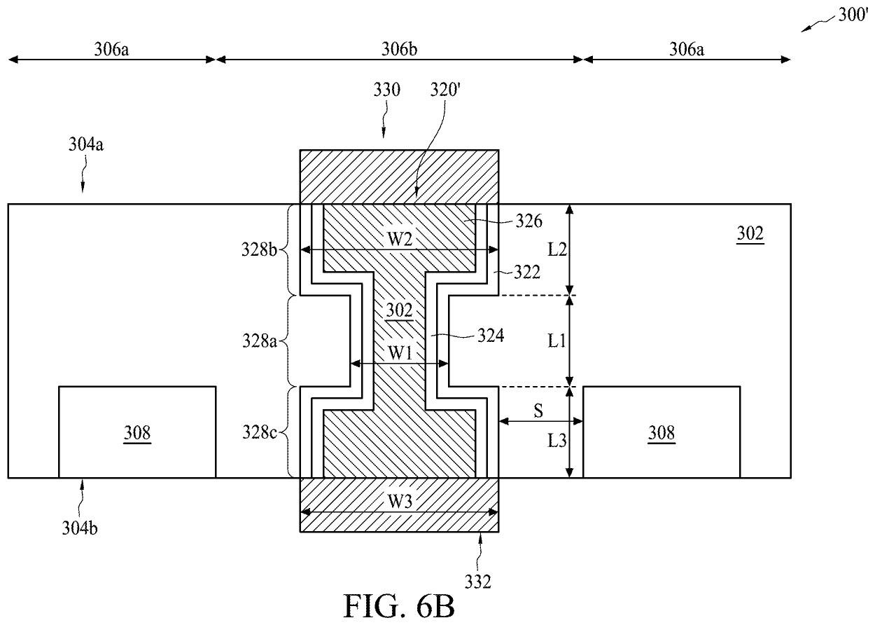

FIGS. 6A to 6B are schematic diagrams illustrating various fabrication stages of the method for preparing a semiconductor structure in accordance with a fourth embodiment of the present disclosure. It should be understood that similar features in the third and fourth embodiments can include similar materials and are depicted by the same numerals, and thus description of such details are omitted in the interest of brevity. Referring to FIG. 6A, a semiconductor substrate 302 can be provided according to step 102. The semiconductor substrate 302 has a front surface 304a and a back surface 304b. In some embodiments, the semiconductor substrate 302 has a plurality of device regions 306a and at least a connection region 306b defined on the semiconductor substrate 302. An active device 308 is disposed in each of the plurality of device regions 306a, as shown in FIG. 6A.

According to step 104, the semiconductor substrate 302 is etched at the back surface 304b to form a first trench 310 in the semiconductor substrate 302. According to step 106, a portion of the first trench 310 is widened at the back surface 304b to form a second trench 312. According to the fourth embodiment, a portion of the first trench 310 is further widened at the front surface 304a of the semiconductor substrate 302 to form a third trench 314, as shown in FIG. 6A. The first trench 310 has a width W1, the second trench 312 has a width W2, and the third trench 314 has a width W3. The width W2 of the second trench 312 and the width W3 of the third trench 314 are greater than the width W1 of the first trench 310. In some embodiments, the width W2 of the second trench 312 and the width W3 of the third trench 314 are different from each other. In alternative embodiments, the width W2 of the second trench 312 and the width W3 of the third trench 314 are similar. According to the fourth embodiment, the third trench 314 and the active device 308 are exposed through the front surface 304a. However, the third trench 314 and the active device 308 are separate from each other by a spacing distance S. Further, the spacing distance S between the third trench 314 and the active device 308 is similar to the width W1 of the first trench 310.

Referring to FIG. 6B, an insulating liner layer 322 is formed on sidewalls and bottom surfaces of the first trench 310, the second trench 312 and the third trench 314. Further, the insulating liner layer 322 is formed on bottom surfaces of the second trench 312 and the third trench 314. A barrier liner layer 324 is formed on the insulating liner layer 322, and over the sidewalls and bottom surfaces of the first trench 310, the second trench 312 and the third trench 314. In some embodiments, a seed layer (not shown) can be formed on the barrier liner layer 324, but the disclosure is not limited thereto.

Still referring to FIG. 6B, after the forming of the barrier liner layer 324 or the seed layer, a conductive material 326 is formed. As shown in FIG. 6B, the first trench 310, the second trench 312 and the third trench 314 are filled with the conductive material 326, according to step 108. Accordingly, a TSV structure 320′ is obtained.

Referring to FIG. 6B, in some embodiments, a conductive member 330 can be disposed on the TSV structure 320′ and in contact with the TSV structure 320′. In some embodiments, the conductive member 330 can be a bonding pad, but the disclosure is not limited thereto. Further, another conductive member 332 can be disposed on the TSV structure 320′ and in contact with the TSV structure 320′. In some embodiments, the conductive member 332 can be a bonding pad, but the disclosure is not limited thereto.

Referring to FIGS. 6B and 3, the FIG. 3 is a top view of the semiconductor structure 300′ provided by the fourth embodiment. It should be noted that the conductive member 330 is omitted from FIG. 3 to emphasize the relationship between the TSV structure 320′ and the active device 308, but those skilled in the art can realize the placement of the conductive member 330 according to FIG. 6B. According to the fourth embodiment, the semiconductor structure 300′ includes the semiconductor substrate 302, the active device 308, and the TSV structure 320′. It should be noted that description of similar features in the third and fourth embodiments are omitted in the interest of brevity, and only the differences are described.

The TSV structure 320′ provided by the fourth embodiment includes a first portion 328a, a second portion 328b and a third portion 328c coupled to each other. Further, the first portion 328a is sandwiched between the second portion 328b and the third portion 328c. The first portion 328a has first sidewalls, the second portion 328b has second sidewalls, and the third portion 328c has third sidewalls. The first sidewalls, the second sidewalls and the third sidewalls are separate from each other. In other words, the first sidewalls of the first portion 328a, the second sidewalls of the second portion 328b and the third sidewalls of the third portion 328c are discontinuous, as shown in FIG. 6B. A length L1 of the first portion 328a is greater than a length L2 of the second portion 328b and a length L3 of the third portion 328c. In some embodiments, the length L2 of the second portion 328b and the length L3 of the third portion 328c are different. In alternative embodiments, the length L2 of the second portion 328b and the length L3 of the third portion 328c are similar.

The first portion 328a has a width W1, the second portion 328b has a width W2, and the third portion 328c has a width W3. The width W2 of the second portion 328b and the width W3 of the third portion 328c are greater than the width W1 of the first portion 328a, as shown in FIG. 6B. A ratio of the width W2 of the second portion 328b to the width W1 of the first portion 328a is between approximately 1.1 and approximately 1.5, but the disclosure is not limited thereto. A ratio of the width W3 of the third portion 328c to the width W1 of the first portion 328a is between approximately 1.1 and approximately 1.5, but the disclosure is not limited thereto. In other words, the TSV structure 320′ includes an H-shaped configuration with the first portion 328a serving as a bridge between the second portion 328b and the third portion 328c. The second portion 328b is exposed through the back surface 304b of the semiconductor substrate 302, while the third portion 328c and the active devices 308 are exposed through the front surface 304a of the semiconductor substrate 302. The spacing distance S between the active device 308 and the third portion 328c of the TSV structure 320′ is similar to the width W1 of the first portion 328a, but the disclosure is not limited thereto. In some embodiments, the semiconductor structure 300′ can include the conductive member 330 disposed on and in contact with the second portion 328b of the TSV structure 320′. In some embodiments, the semiconductor structure 300′ can include the conductive member 332 disposed on and in contact with the third portion 328c of the TSV structure 320′.

As mentioned above, the spacing distance S between the third portion 328c of the TSV structure 320′ and the active device 308 is similar to the width W1 of the first portion 328a of the TSV structure 320′. Therefore, stress induced by the TSV structure 320′ on the active device 308 is negligible. More importantly, since the width W2 of the second portion 328b and the width W3 of the third portion 328c are greater than the width W1 of the first portion 328a, a contact area between the conductive member 330 and the second portion 328b is increased, and a contact area between the conductive member 332 and the third portion 328b is increased. Accordingly, the EM failure issue between the TSV structure 320′ and the conductive members 330 and 332 is mitigated.

In the present disclosure, the TSV structure 220 and 320 include multiple widths. The TSV structure 220 and 320 include the second portions 228b and 328b having widths greater than those of the first portions 228a and 328a. Further, the second portions 228b and 328b are in contact with the conductive members 230 and 330. Because a contact area between the second portions 228b and 328b of the TSV structures 220 and 320 and the conductive members 230 and 330 is increased, the EM failure issue between the TSV structures 220 and 320 and the conductive members 230 and 330 is mitigated.

In contrast, with a comparative method applied without forming the second portion having greater width, the TSV structure has less contact area between the conductive member and the TSV structure. Accordingly, with the comparative method, EM failure is accelerated, and thus reliability of the semiconductor structure is adversely affected.

One aspect of the present disclosure provides a semiconductor structure. The semiconductor structure includes a semiconductor substrate, an active device, and a TSV structure. The semiconductor substrate has a first surface and a second surface opposite to the first surface. The active device is disposed in the semiconductor substrate at the first surface. The TSV structure extends through the semiconductor substrate from the first surface to the second surface. In some embodiments, the TSV structure includes a first portion and a second portion coupled to the first portion. The first portion of the TSV structure has a first width, the second portion of the TSV structure has a second width, and the second width of the second portion is greater than the first width of the first portion.

Another aspect of the present disclosure provides a method for preparing a semiconductor structure. The method includes the following steps. A semiconductor substrate has a first surface and a second surface opposite to the first surface. The semiconductor substrate is etched at the first surface to form a first trench in the semiconductor substrate. A portion of the first trench is widened at the first surface to form a second trench in the semiconductor substrate. The first trench and the second trench are filled with a conductive material. In some embodiments, the first trench has a first width and the second trench has a second width. In some embodiments, a ratio of the second width to the first width is between approximately 1.1 and approximately 1.5.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor structure comprising:
a semiconductor substrate having a first surface and a second surface opposite to the first surface;
an active device disposed in the semiconductor substrate at the first surface; and
a TSV structure extending through the semiconductor substrate from the first surface to the second surface, wherein the TSV structure comprises:
a first portion having a first width; and
a second portion coupled to the first portion and having a second width greater than the first width.

2. The semiconductor structure of claim 1, wherein the first portion is exposed through the second surface of the semiconductor substrate, and the second portion is exposed through the first surface of the semiconductor substrate.

3. The semiconductor structure of claim 2, wherein a spacing distance between the active device and the second portion of the TSV structure is similar to the first width.

4. The semiconductor structure of claim 1, wherein the first portion is exposed through the first surface of the semiconductor substrate, and the second portion is exposed through the second surface of the semiconductor substrate.

5. The semiconductor structure of claim 4, wherein a spacing distance between the active device and the first portion of the TSV structure is similar to the first width.

6. The semiconductor structure of claim 1, further comprising a third portion coupled to the first portion and having a third width greater than the first width.

7. The semiconductor structure of claim 6, wherein the second portion is exposed through the first surface of the semiconductor substrate, the third portion is exposed through the second surface of the semiconductor substrate, and the first portion is between the second portion and the third portion.

8. The semiconductor structure of claim 1, wherein a ratio of the second width to the first width is between approximately 1.1 and approximately 1.5.

9. The semiconductor structure of claim 1, wherein the first portion has a first length, and the second portion has a second length less than the first length.

10. The semiconductor structure of claim 1, wherein the first portion comprises first sidewalls, the second portion comprises second sidewalls, and the first sidewalls are separate from the second sidewalls.

11. The semiconductor structure of claim 1, wherein the TSV structure comprises a conductive material and a barrier liner layer located between the semiconductor substrate and the conductive material.

12. The semiconductor structure of claim 1, further comprising a conductive member disposed on and in contact with the second portion of the TSV structure.

13. A method for forming a semiconductor structure, comprising:
etching a semiconductor substrate from a first surface to a second surface opposite to the first surface to form a first trench in the semiconductor substrate;
widening a portion of the first trench at the first surface to form a second trench in the semiconductor substrate; and
filling the first trench and the second trench with a conductive material, wherein the first trench has a first width, the second trench has a second width greater than the first width.

14. The method of claim 13, wherein the widening of the first trench further comprises:
disposing a patterned photoresist over the first surface to expose the first trench and a portion of the semiconductor substrate; and
removing the portion of the semiconductor substrate to widen the first trench to form the second trench.

15. The method of claim 13, wherein a ratio of the second width to the first width is between approximately 1.1 and approximately 1.5.

16. The method of claim 13, further comprising disposing an active device in the semiconductor substrate at the first surface, wherein a spacing distance between the second trench and the active device is similar to the first width of the first trench.

17. The method of claim 13, further comprising disposing an active device in the semiconductor substrate at the second surface, wherein a spacing distance between the first trench and the active device is similar to the first width of the first trench.

18. The method of claim 13, further comprising widening the first trench at the second surface of the semiconductor substrate to form a third trench having a third width greater than the first width.

19. The method of claim 13, wherein a depth of the first trench is greater than a depth of the second trench.

20. The method of claim 13, further comprising forming a barrier liner layer on sidewalls and bottom surfaces of the first trench and the second trench prior to the forming of the conductive material.
